(19) United States
(12) Patent Application Publication
(10) Pub. No.: US 2025/0054892 A1
(43) Pub. Date: Feb. 13, 2025

(54) PACKAGE STRUCTURE AND METHOD FOR FABRICATING THE SAME

(71) Applicant: Taiwan Semiconductor Manufacturing Company, Ltd., Hsinchu (TW)

(72) Inventors: Chao-Wei Chiu, Hsinchu City (TW); Wei-Yu Chen, Taipei City (TW); Hsin Liang Chen, New Taipei City (TW); Hao-Jan Shih, Hsinchu (TW); Hsiu-Jen Lin, Hsinchu County (TW); Ching-Hua Hsieh, Hsinchu (TW)

(73) Assignee: Taiwan Semiconductor Manufacturing Company, Ltd., Hsinchu (TW)

(21) Appl. No.: 18/403,757

(22) Filed: Jan. 4, 2024

Related U.S. Application Data
(60) Provisional application No. 63/531,818, filed on Aug. 10, 2023.
(60) Provisional application No. 63/610,420, filed on Dec. 15, 2023.

(51) Int. Cl. H01L 23/00

(52) U.S. Cl. CPC H01L 24/14; H01L 24/11; H01L 24/16; H01L 24/32; H01L 24/73; H01L 24/81; H01L 24/83; H01L 24/92; H01L 24/03; H01L 24/05; H01L 24/06; H01L 2224/0345; H01L 2224/03452; H01L 2224/03912; H01L 2224/05582; H01L 2224/05647; H01L 2224/05666; H01L 2224/0603; H01L 2224/1146; H01L 2224/11903; H01L 2224/1403; H01L 2224/14132; H01L 2224/16145; H01L 2224/32145; H01L 2224/73204; H01L 2224/81203; H01L 2224/83203; H01L 2224/9211

(57) ABSTRACT

A package structure including a first substrate and a second substrate is provided. The first substrate includes first bumps with first lateral dimension and second bumps with second lateral dimension. The first bumps are distributed in a first region of the first substrate, and the second bumps are distributed in the second region of the first substrate, wherein the first lateral dimension is greater than the second lateral dimension, and a first bump height of the first bumps is smaller than a second bump height of the second bumps. The second substrate includes conductive terminals electrically connected to the first bumps and the second bumps.

### CROSS-REFERENCE TO RELATED APPLICATION

This application claims the priority benefit of U.S. provisional applications Ser. Nos. 63/531,818 and 63/610,420, filed on Aug. 10, 2023 and Dec. 15, 2023 respectively. The entirety of each of the above-mentioned patent applications is hereby incorporated by reference herein and made a part of this specification.

### BACKGROUND

In packaging of semiconductor devices, after individual semiconductor dies are manufactured and packaged, the packaged semiconductor devices may be mounted on a packaging substrate with other electronic components, such as other semiconductor dies, to form a semiconductor device. Currently, Chip-on-Wafer (CoW) bonding process for bonding and electrically connecting semiconductor dies and semiconductor wafer is widely utilized. The reliability of the CoW bonding process is highly related to the bonding condition of conductive terminals between the semiconductor dies and the semiconductor wafer.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 through FIG. 4 are cross-sectional views schematically illustrating a process flow for fabricating a Chip-on-Wafer-on-Substrate (CoWoS) structure in accordance with some embodiments of the present disclosure.

FIG. 5A through FIG. 5H are cross-sectional views schematically illustrating a process flow for fabricating a semiconductor wafer including bumps with various lateral dimensions in accordance with some embodiments of the present disclosure.

FIG. 6A is a top view schematically illustrating a mask utilized in the photolithography process as shown in FIG. 5B.

FIG. 6B is a top view schematically illustrating a mask utilized in the photolithography process as shown in FIG. 5F.

FIG. 7A through FIG. 7H are cross-sectional views schematically illustrating a process flow for fabricating a semiconductor wafer including bumps with various lateral dimensions in accordance with some embodiments of the present disclosure.

FIG. 8A is a top view schematically illustrating a mask utilized in the photolithography process as shown in FIG. 7B.

FIG. 8B is a top view schematically illustrating a mask utilized in the photolithography process as shown in FIG. 7F.

FIG. 9A through FIG. 9L are cross-sectional views schematically illustrating a process flow for fabricating a semiconductor wafer including bumps with various lateral dimensions in accordance with some embodiments of the present disclosure.

FIG. 10A is a top view schematically illustrating a mask utilized in the photolithography process as shown in FIG. 9B.

FIG. 10B is a top view schematically illustrating a mask utilized in the photolithography process as shown in FIG. 9F.

FIG. 10C is a top view schematically illustrating a mask utilized in the photolithography process as shown in FIG. 9J.

FIG. 11 through FIG. 13 are cross-sectional views schematically illustrating a process flow for fabricating a package structure in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. Where applicable, the term “substantially” may also relate to 90% or higher, such as 95% or higher, especially 99% or higher, including 100%. Furthermore, terms such as “substantially parallel” or “substantially perpendicular” are to be interpreted as not to exclude insignificant deviation from the specified arrangement and may include for example deviations of up to 10°. The word “substantially” does not exclude “completely” e.g., a composition which is “substantially free” from Y may be completely free from Y.

Semiconductor dies each having bumps with multi-critical dimension (CD) design or multi-pitch design are gradually utilized. Take a Chip-on-Wafer-on-Substrate (CoWoS) structure including semiconductor dies with multi-CD design as an example, solder extrusion and non-conductive film (NCF) bleeding occurred during the Chip-on-Wafer (CoW) bonding process of the stacked semiconductor dies should be well controlled such that unaccepted cold joint and/or short circuit between the stacked semiconductor dies can be prevented. Accordingly, the joint yields between stacked semiconductor dies may increase.

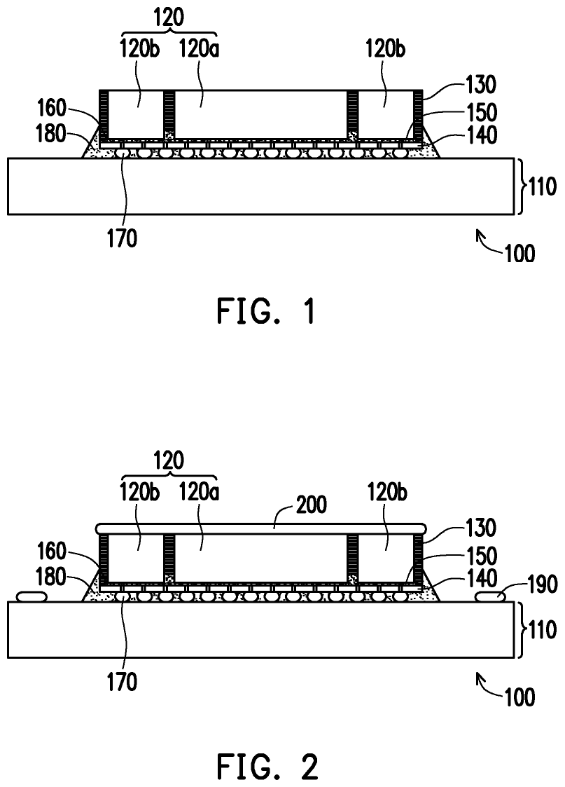

FIG. 1 through FIG. 4 are cross-sectional views schematically illustrating a process flow for fabricating a Chip-on-Wafer-on-Substrate (CoWoS) structure in accordance with some embodiments of the present disclosure.

Referring to FIG. 1, a package 100 including a packaging substrate 110, semiconductor dies 120 and an insulating encapsulation 130 is provided. The semiconductor dies 120 are disposed on and electrically connected to the packaging substrate 110, and the insulating encapsulation 130 laterally encapsulates the semiconductor dies 120. In some embodiments, as illustrated in FIG. 1, a Chip-on-Wafer-on-Substrate (CoWoS) package 100 is provided. The CoWoS package 100 may include a packaging substrate 110, semiconductor dies 120, an insulating encapsulation 130, an interposer substrate 140, conductive terminals 150, an underfill 160, conductive terminals 170 and an underfill 180.

The packaging substrate 110 may be a printed circuit board. The semiconductor dies 120 may include at least one semiconductor die 120a and at least one semiconductor die 120b. In some embodiments, the semiconductor die 120a includes a System-on-Chip (SoC) die, and the semiconductor die 120b includes a High-Bandwidth-Memory (HBM) cube including stacked HBM memory dies and controller die for controlling operation of the stacked HBM memory dies. In some other embodiments, the semiconductor die 120a and 120b may be System on Integrated Circuit (SoIC) dies with various functions. The semiconductor dies 120 are disposed on the interposer substrate 140 and electrically connected to the interposer substrate 140 through the conductive terminals 150. The semiconductor dies 120 are bonded with the interposer substrate 140 through the conductive terminals 150 by a Chip-on-Wafer (CoW) bonding process. The conductive terminals 150 are disposed between the semiconductor dies 120 and the interposer substrate 140. The conductive terminals 150 may be or include micro-bumps for electrically connecting the semiconductor dies 120 and the interposer substrate 140. The underfill 160 is disposed on the interposer substrate 140. The underfill 610 fills the gap between the semiconductor dies 120 and the interposer substrate 140 to laterally encapsulate the conductive terminals 150. The material of the underfill 160 may be or include epoxy resin or other suitable dielectric materials.

The insulating encapsulation 130 is disposed on the interposer substrate 140 to laterally encapsulate the semiconductor dies 120 and the underfill 160. The insulating encapsulation 130 is not in contact with the foot portion 124 of the lid 210. As illustrated in FIG. 1, the top surfaces (e.g., the back surfaces) of the semiconductor dies 120 are substantially level with the top surface of the insulating encapsulation 130, and the sidewalls of the insulating encapsulation 130 are substantially aligned with the sidewalls of the interposer substrate 140. The conductive terminals 170 are disposed on the bottom surface of the interposer substrate 140, and the interposer substrate 140 is electrically connected to the packaging substrate 110 through the conductive terminals 170. The conductive terminals 170 may be or include Controlled Collapse Chip Connection bumps (C4 bumps) for electrically connecting the interposer substrate 140 and the packaging substrate 110. The underfill 180 is disposed on the packaging substrate 110. The underfill 180 fills the gap between the interposer substrate 140 and the packaging substrate 110 to laterally encapsulate the conductive terminals 170. Furthermore, the underfill 180 covers sidewalls of the interposer substrate 140 as well as lower portions of sidewalls of insulating encapsulation 130.

As illustrated in FIG. 1, the semiconductor dies 120 are electrically connected to the packaging substrate 110 through the interposer substrate 140, the conductive terminals 150 and the conductive terminals 170. The interposer substrate 140 may be a silicon interposer substrate with fine line pitch (e.g., sub-um pitch), an organic interposer substrate with less aggressive fine line pitch (e.g., 4 um pitch) or an interposer substrate with Local Silicon Interconnect (LSI) die. In an embodiment where the interposer substrate 140 is a silicon interposer substrate, the CoWoS package 100 is so-called a CoWoS-S package. In an embodiment where the interposer substrate 140 is an organic interposer substrate, the CoWoS package 100 is so-called a CoWoS-R package. In an embodiment where the interposer substrate 140 is an interposer substrate with Local Silicon Interconnect (LSI) die, the CoWoS package 100 is so-called a CoWoS-L package.

Although an CoWoS package 100 is shown in FIG. 1 for illustration, the configuration of the package 100 is not limited to CoWoS package, an integrated fanout assembly-on-Substrate (InFO-oS) package may be utilized in embodiments of the present invention.

Referring to FIG. 2, an adhesive 190 is applied on the packaging substrate 110, and a thermal interface material (TIM) 200 is applied on the top surfaces (e.g., the back surfaces) of the semiconductor dies 120 and the top surface of the insulating encapsulation 130. The material of the adhesive 190 may be or include thermally conductive adhesive, silicone based adhesive or epoxy resin based adhesive. The material of the adhesive may be or include rubber based having curing promoting material. The thermal interface material 200 may be or include silicone-based thermal interface material, metallic thermal interface material, combinations thereof or the like. In the present embodiments, a film-type thermal interface material 200 is provided and attached on the top surfaces (e.g., the back surfaces) of the semiconductor dies 120 and the top surface of the insulating encapsulation 130.

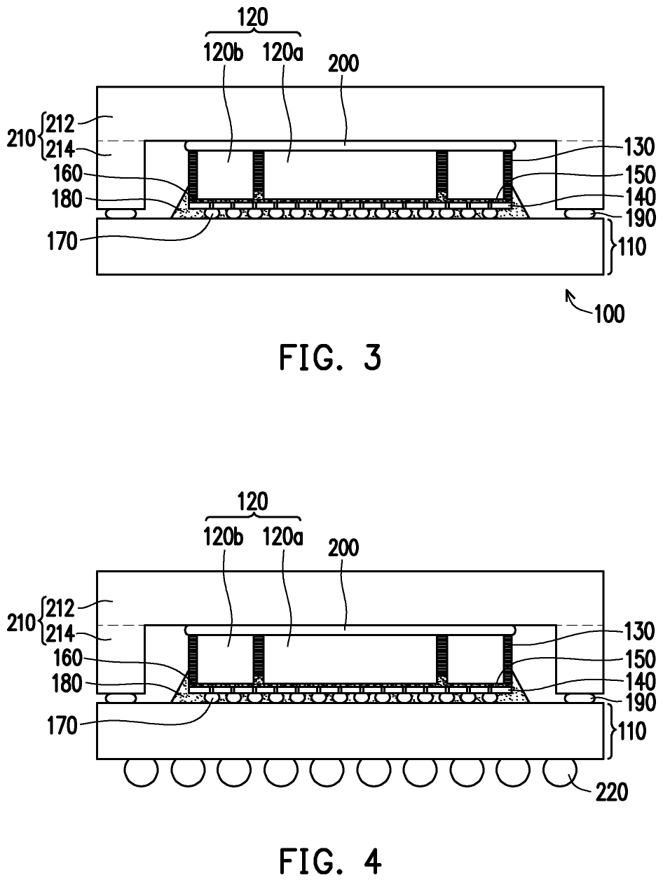

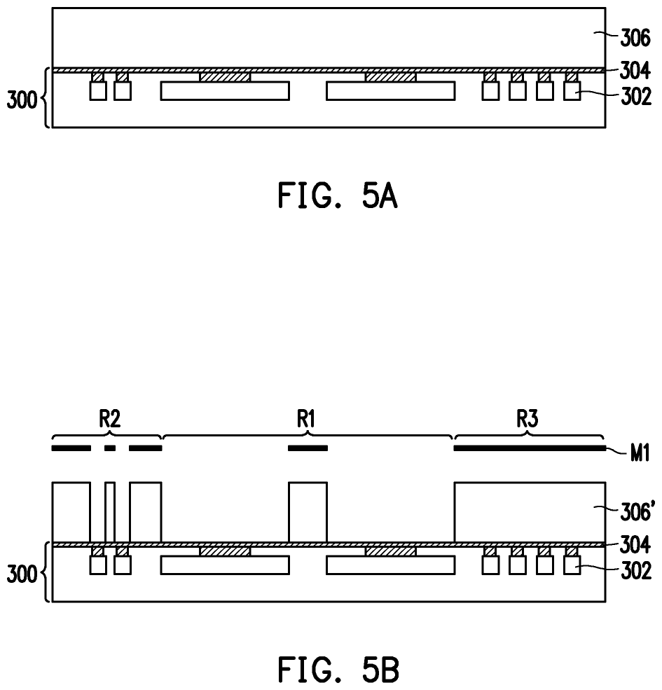

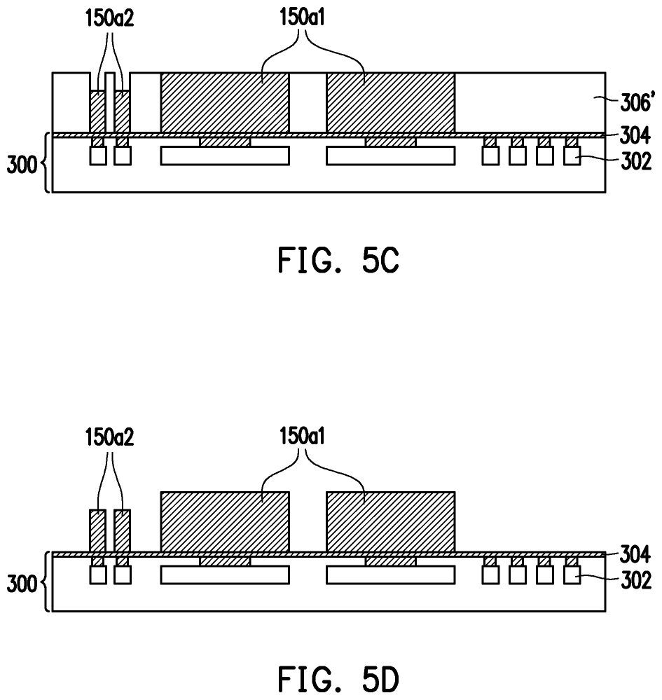

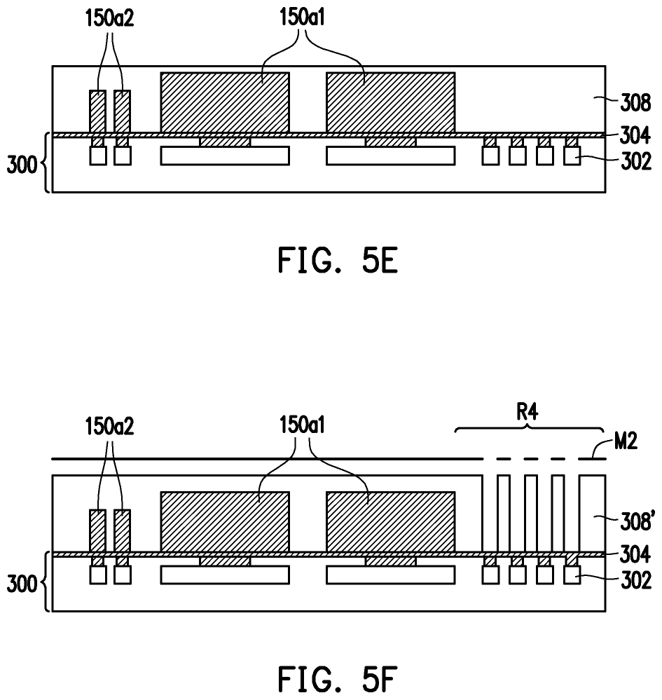

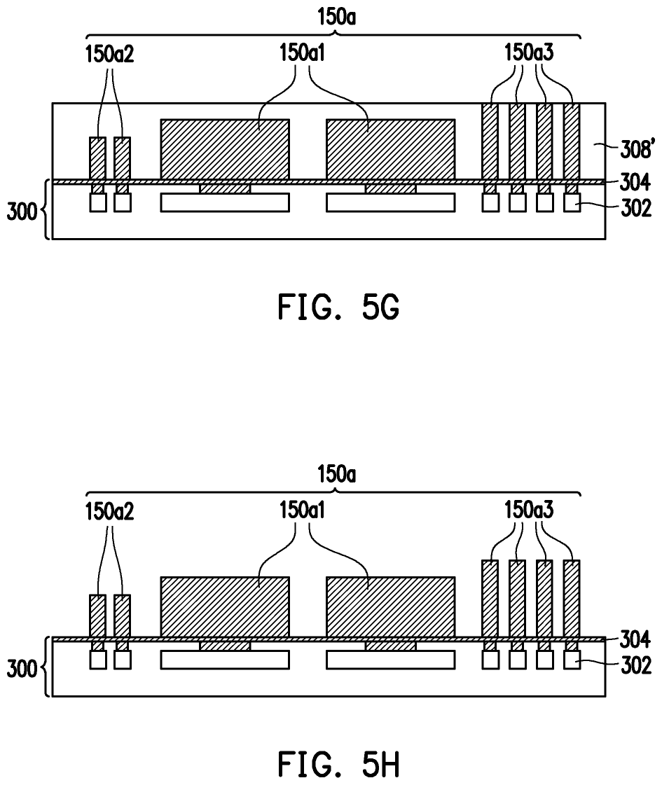

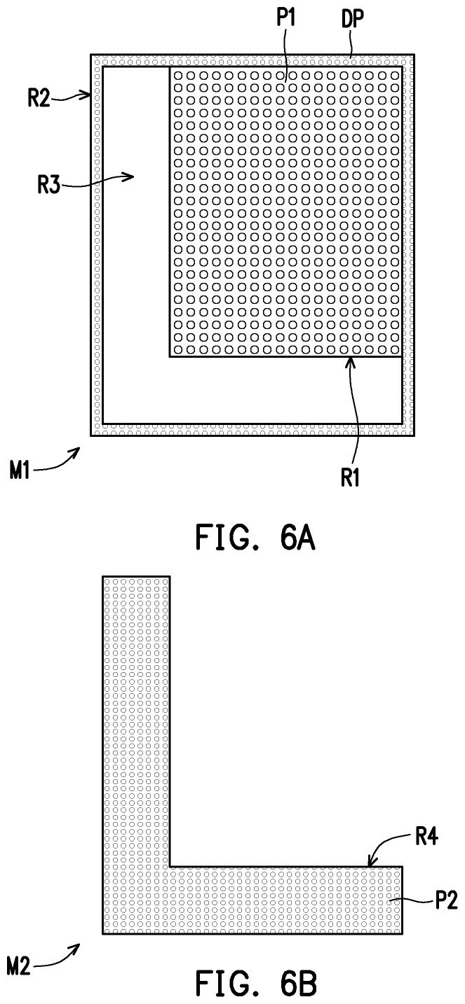

Referring to FIG. 3, after the adhesive 190 and the thermal interface material 200 are applied, a lid 210 is provided and attached onto the CoWoS package 100. The lid 210 is mounted onto the packaging substrate 110 to cover the semiconductor dies 120 encapsulated by the insulating encapsulation 130. The lid 210 includes a cover portion 212 and a foot portion 214 extending from the cover portion 212 to the packaging substrate 110. The cover portion 212 covers the semiconductor dies 120 and the insulating encapsulation 130. The bottom surface of the foot portion 214 is attached to the packaging substrate 110 through the adhesive 190, and the cover portion 212 of the lid 210 is attached to the package 100 through the thermal interface material 200. The lid 210 may further include an alignment notch 216 formed at a corner of the lid 10 such that the lid 210 may be assembled with the packaging substrate 110 correctly and rapidly. The details of the lid 210 are described in accompany with FIG. 5 and FIG. 6.

Referring to FIG. 4, conductive terminals 220 are formed on the bottom surface of the packaging substrate 110. The conductive terminals 112 formed on the bottom surface of the packaging substrate 110 may be solder balls arranged in array, and the solder balls may be formed by, for example, a ball mount process following by a reflowing process. The packaging substrate 110 may be a ball grid array (BGA) circuit board. After the conductive terminals 220 are formed on the bottom surface of the packaging substrate 110, a singulation process may be performed to cut the packaging substrate 110 to obtain singulated semiconductor devices as shown in FIG. 4.

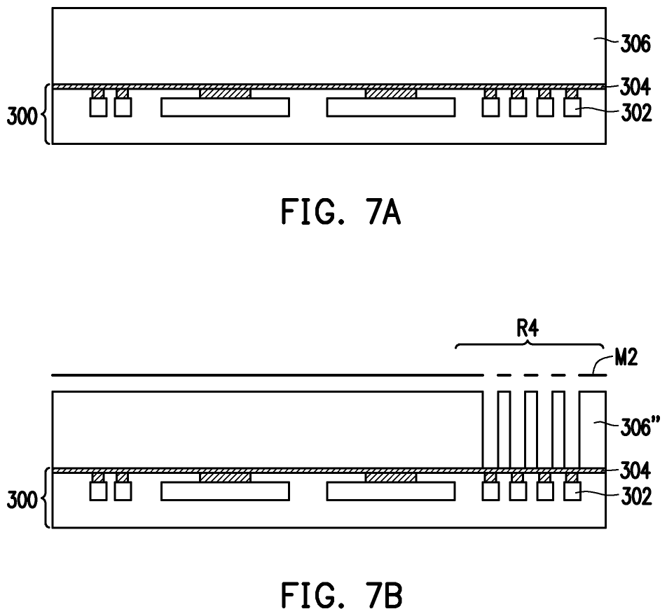

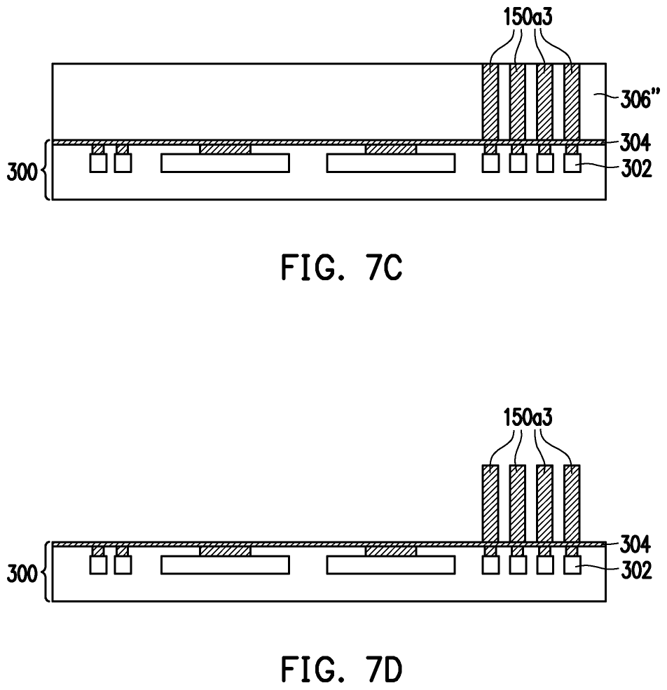

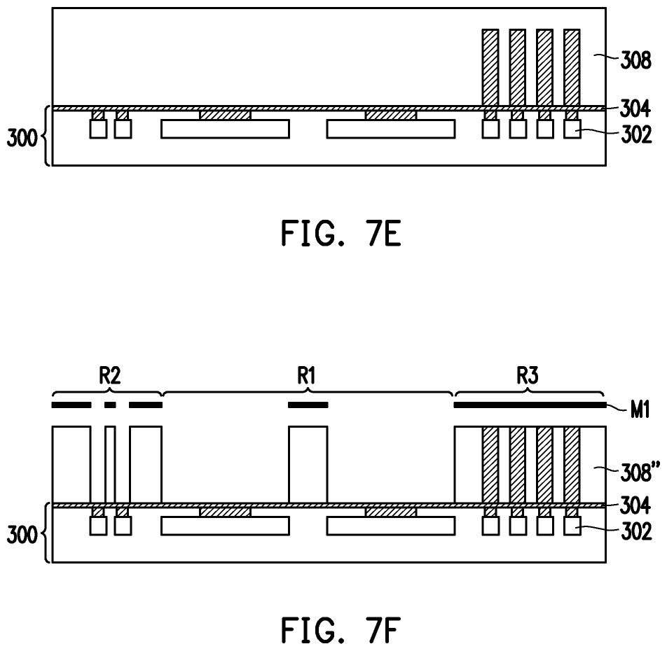

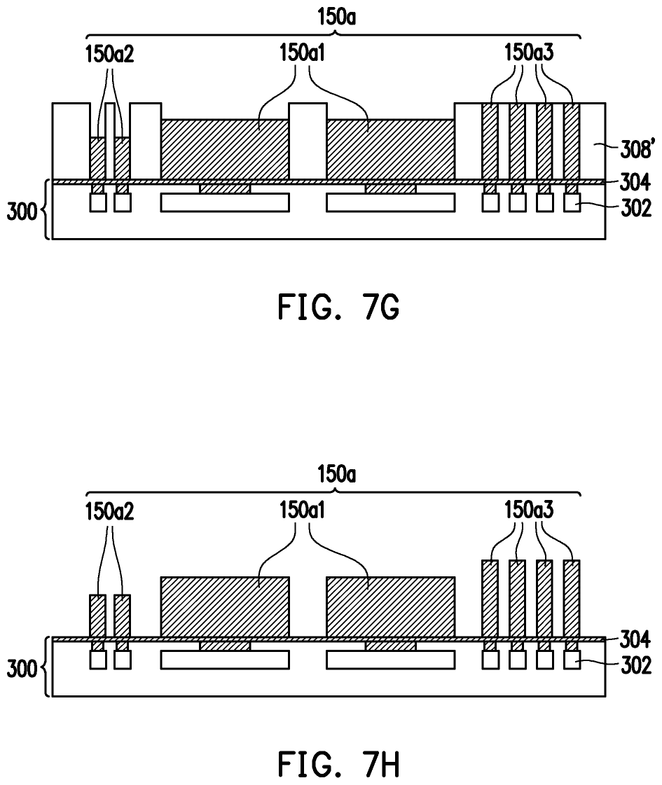

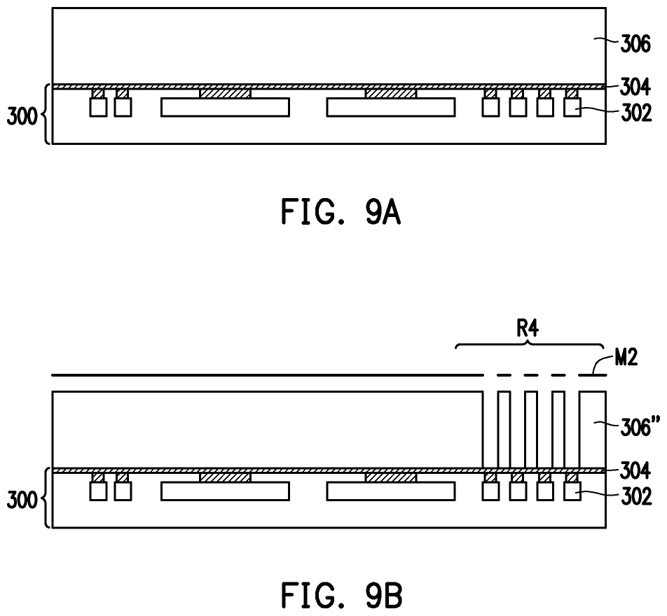

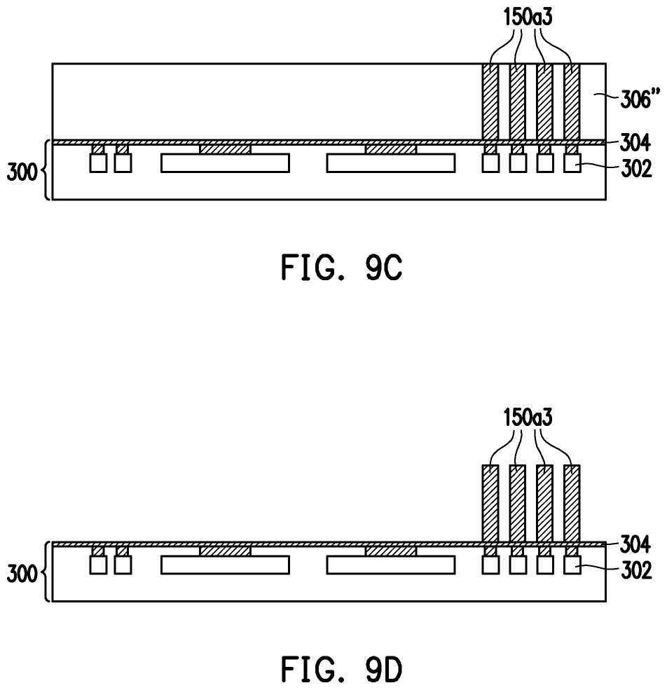

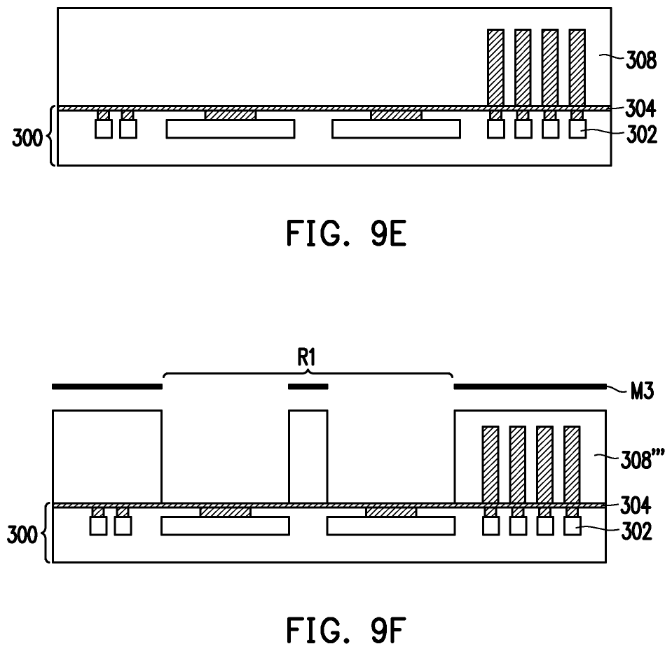

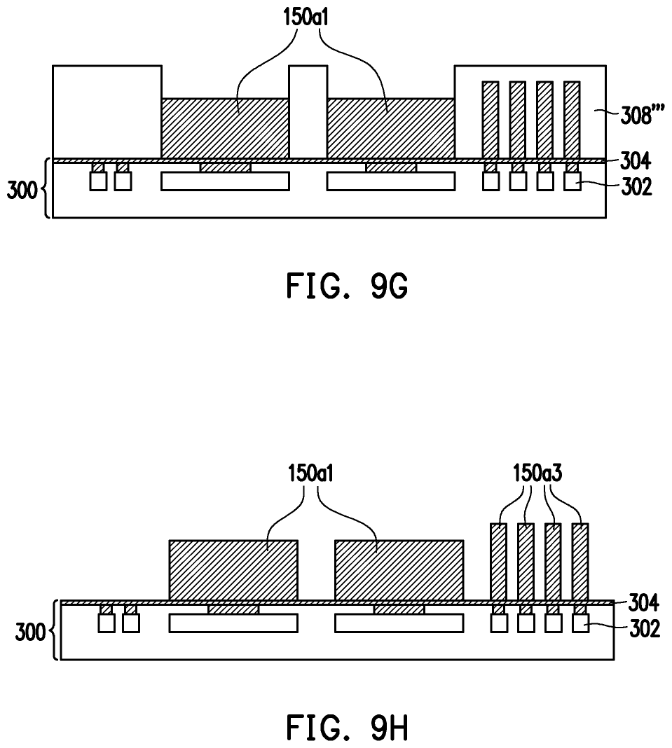

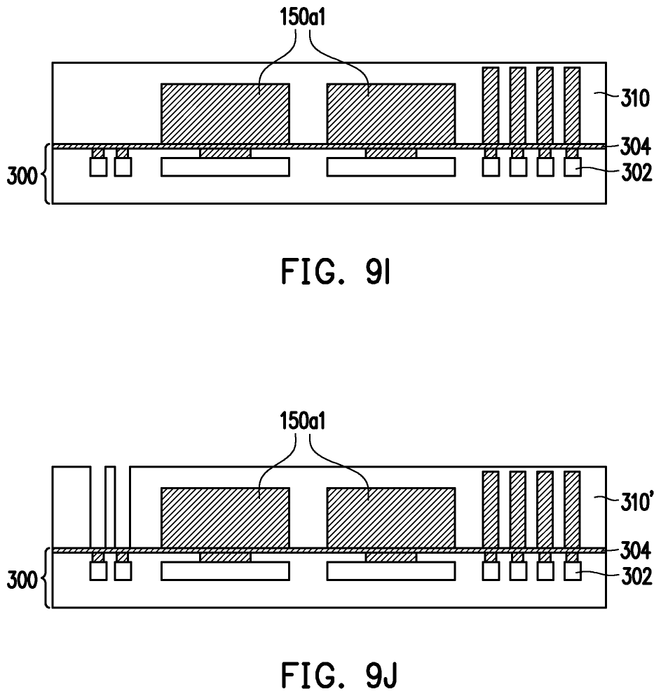

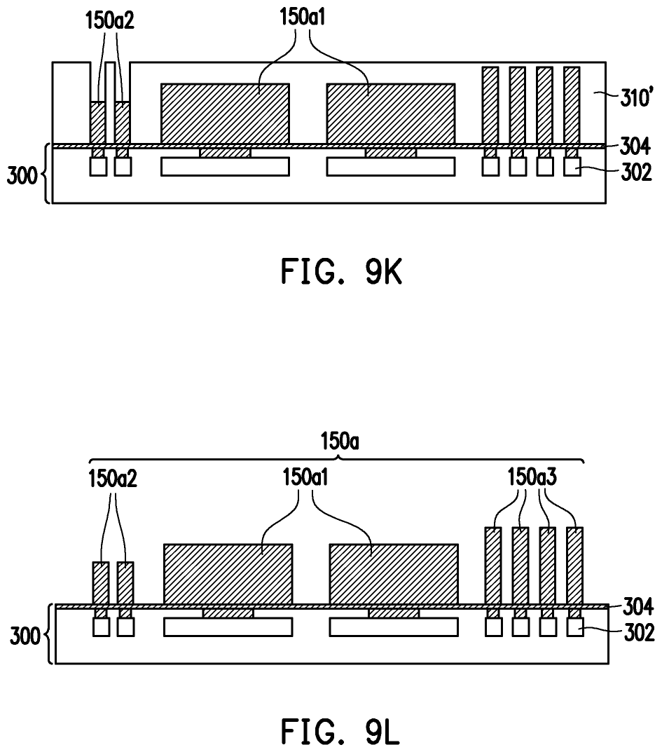

Details of various fabrication processes of bumps on the interposer substrate 140 are described in accompany with FIG. 5A through FIG. 5H, FIG. 7A through FIG. 7H, and FIG. 9A through FIG. 9L.

FIG. 5A through FIG. 5H are cross-sectional views schematically illustrating a process flow for fabricating a semiconductor wafer 300 including bumps 150a with various lateral dimensions in accordance with some embodiments of the present disclosure. FIG. 6A is a top view schematically illustrating a mask utilized in the photolithography process as shown in FIG. 5B. FIG. 6B is a top view schematically illustrating a mask utilized in the photolithography process as shown in FIG. 5F. The following processes for fabricating the semiconductor wafer 300 is utilized to fabricate or prepare the interposer substrate 140 as illustrated in FIG. 1 through FIG. 4. That is, the semiconductor wafer 300 is equivalent to the interposer substrate 140 as illustrated in FIG. 1 through FIG. 4.

Referring to FIG. 5A, a semiconductor wafer 300 including conductors 302 distributed therein is provided. In some embodiments, the semiconductor wafer 300 includes semiconductor chips arranged in array, and the semiconductor chips in the semiconductor wafer 300 may be logic dies, System-on-Chip (SoC) dies or other suitable semiconductor dies. The semiconductor wafer 300 may include a semiconductor substrate, through substrate vias embedded in the semiconductor substrate, and an interconnect structure disposed on the semiconductor substrate, wherein the through substrate vias are electrically connected to the interconnect structure. The semiconductor substrate of the semiconductor wafer 300 may include a crystalline silicon wafer. The semiconductor substrate may include various doped regions depending on design requirements (e.g., p-type semiconductor substrate or n-type semiconductor substrate). In some embodiments, the doped regions may be doped with p-type or n-type dopants. The doped regions may be doped with p-type dopants, such as boron or BF₂; n-type dopants, such as phosphorus or arsenic; and/or combinations thereof. The doped regions may be configured for n-type Fin-type Field Effect Transistors (FinFETs) and/or p-type FinFETs. In some alternative embodiments, the semiconductor substrate may be made of some other suitable elemental semiconductor, such as diamond or germanium; a suitable compound semiconductor, such as gallium arsenide, silicon carbide, indium arsenide, or indium phosphide; or a suitable alloy semiconductor, such as silicon germanium carbide, gallium arsenic phosphide, or gallium indium phosphide.

The through substrate vias may be formed by forming recesses in the semiconductor substrate by, for example, etching, milling, laser techniques, a combination thereof, and/or the like. A thin barrier layer may be conformally deposited over the front side of the semiconductor substrate and in the openings, such as by chemical vapor deposition (CVD), atomic layer deposition (ALD), physical vapor deposition (PVD), thermal oxidation, a combination thereof, and/or the like. The barrier layer may include a nitride or an oxynitride, such as titanium nitride, titanium oxynitride, tantalum nitride, tantalum oxynitride, tungsten nitride, a combination thereof, and/or the like. A conductive material is deposited over the thin barrier layer and in the openings. The conductive material may be formed by an electro-chemical plating process, CVD, ALD, PVD, a combination thereof, and/or the like. Examples of conductive materials are copper, tungsten, aluminum, silver, gold, a combination thereof, and/or the like. Excess conductive material and barrier layer may be removed from the front side of the semiconductor substrate by, for example, chemical mechanical polishing (CMP). Thus, in some embodiments, the through substrate vias may include a conductive material and a thin barrier layer between the conductive material and the semiconductor substrate. In some embodiments, the through substrate vias may extend through one or more layers of the interconnect structure and protrude into the semiconductor substrate. The through substrate vias may be buried in the semiconductor substrate and the interconnect structure of the semiconductor wafer 300. The through substrate vias are not revealed from a back surface of the semiconductor substrate at this stage.

The interconnect structure may include one or more dielectric layers (for example, one or more interlayer dielectric (ILD) layers, intermetal dielectric (IMD) layers, or the like) and interconnect wirings embedded in the one or more dielectric layers, and the interconnect wirings are electrically connected to the semiconductor devices (e.g., FinFETs) formed in the semiconductor substrate. The material of the one or more dielectric layers may include silicon oxide (SiOₓ, where x>0), silicon nitride (SiNₓ, where x>0), silicon oxynitride (SiOₓN_{y}, where x>0 and y>0) or other suitable dielectric material. The interconnect wirings may include metallic wirings. For example, the interconnect wirings include copper wirings, copper pads, aluminum pads or combinations thereof.

In some other embodiments, the semiconductor wafer 300 includes a semiconductor interposer wafer, such as a silicon interposer wafer or other suitable semiconductor interposer wafer. The semiconductor wafer 300 may include a semiconductor substrate (e.g., a semiconductor substrate) and through substrate vias embedded in the semiconductor substrate. In some alternative embodiments, the semiconductor wafer 300 is a reconstructed wafer including semiconductor dies laterally encapsulated by an insulating encapsulant.

A seed layer 304 is formed on a surface of the semiconductor wafer 300 such that revealed surfaces of the conductors 302 (e.g., the interconnect wirings and/or the through substrate vias mentioned above) are covered by and in contact with the seed layer 304. The seed layer 304 is formed on the surface of the semiconductor wafer 300 through a Physical Vapor Deposition (PVD) process, a Chemical Vapor Deposition (CVD) process, or other suitable film deposition process. The seed layer 304 may be or include a Ti/Cu composited layer deposited by a sputtering process.

After depositing the seed layer 304 over the semiconductor wafer 300, a photoresist layer 306 is formed on the seed layer 304. In some embodiments, the photoresist layer 306 is formed on the seed layer 304 by a spin-coating process followed by a baking process.

Referring to FIG. 5B and FIG. 6A, after forming the photoresist layer 306, a patterning process (e.g., a photolithography process followed by a development process) of the photoresist layer 306 is performed such that a patterned photoresist layer 306′ is formed on the seed layer 304. Portions of the seed layer 304 are revealed by openings of the patterned photoresist layer 306′. A mask M1 illustrated in FIG. 6A is provided and a photolithography process followed by a development process is performed by using the mask M1 illustrated in FIG. 6A such that the pattern on the mask M1 can be transferred onto the patterned photoresist layer 306′.

As illustrated in FIG. 6A, the mask M1 may include multiple unit patterns arranged in array although only one unit pattern is illustrated in FIG. 6A. The unit pattern of the mask M1 includes a large CD pattern P1 and a dummy pattern DP surrounding the large CD pattern P1, wherein the large CD pattern P1 is distributed in a region R1, and the dummy pattern DP is distributed in the periphery region R2. Furthermore, a pattern-free region R3 abuts the region R1 as well as the periphery region R2 such that the region R1 and the pattern-free region R3 are laterally surrounded by the periphery region R2.

After forming the patterned photoresist layer 306′, the mask M1 is removed and a cleaning process may be performed.

Referring to FIG. 5C, a plating process is performed such that bumps 150a1 with large CD and bumps (e.g., dummy bumps) 150a2 with small CD are formed on the revealed portions of the seed layer 304. The arrangement pitch and CD of the bumps 150a1 are determined by the large CD pattern P1 distributed in the region R1, and the arrangement pitch and CD of the bumps 150a2 are determined by the dummy pattern DP distributed in the periphery region R2. In some embodiments, the lateral dimension of the bumps 150a1 ranges from about 40 to about 50 micrometers, and the lateral dimension of the bumps 150a2 ranges from about 5 micrometers to about 7 micrometers. For example, the lateral dimension of the bumps 150a1 is about 45 micrometers, and the lateral dimension of the bumps 150a2 is about 6 micrometers.

During the plating process, the bumps 150a1 and the bumps 150a2 are formed by different deposition rates due to different lateral dimensions of the revealed portions of the seed layer 304. Accordingly, the height of the bumps 150a1 may be greater than the height of the bumps 150a2. In some embodiments, the height difference between the bumps 150a1 and the bumps 150a2 is less than or substantially equal to 2 micrometers.

Referring to FIG. 5D, after forming the bumps 150a1 and 150a2, the patterned photoresist layer 306′ is removed through a photoresist stripping process. In some embodiments, the photoresist stripping process includes an ash process or other suitable removal process of the patterned photoresist layer 306′.

After the patterned photoresist layer 306′ is removed, portions of the seed layer 304 that are uncovered by the bumps 150a1 and 150a2 are revealed.

Referring to FIG. 5E, a photoresist layer 308 is formed on the revealed portions of the seed layer 304 as well as the bumps 150a1 and 150a2. In some embodiments, the photoresist layer 308 is formed on the seed layer 304 and the bumps 150a1 and 150a2 by a spin-coating process followed by a baking process. As illustrated in FIG. 5E, the thickness of the photoresist layer 308 is sufficient to entirely cover the bumps 150a1 and 150a2.

Referring to FIG. 5F and FIG. 6B, after forming the photoresist layer 308, a patterning process (e.g., a photolithography process followed by a development process) of the photoresist layer 308 is performed such that a patterned photoresist layer 308′ is formed on the seed layer 304 as well as the bumps 150a1 and 150a2. Portions of the seed layer 304 are revealed by openings of the patterned photoresist layer 308′. A mask M2 illustrated in FIG. 6B is provided and a photolithography process followed by a development process is performed by using the mask M2 illustrated in FIG. 6B such that the pattern on the mask M2 can be transferred onto the patterned photoresist layer 308′.

As illustrated in FIG. 6B, the mask M2 may include multiple unit patterns arranged in array although only one unit pattern is illustrated in FIG. 6B. The unit pattern of the mask M2 includes a small CD pattern P2, wherein the small CD pattern P2 is distributed in a region R4, and the region R4 is corresponding to the pattern-free region R3 as illustrated in FIG. 6A. After forming the patterned photoresist layer 308′, the mask M2 is removed and a cleaning process may be performed.

Referring to FIG. 5G, a plating process is performed such that bumps 150a3 with small CD are formed on the revealed portions of the seed layer 304. The arrangement pitch and CD of the bumps 150a3 may be substantially identical with the arrangement pitch and CD of the bumps 150a2. The arrangement pitch and CD of the bumps 150a3 are determined by the large CD pattern P2 distributed in the region R4. In some embodiments, the lateral dimension of the bumps 150a3 ranges from about 5 micrometers to about 7 micrometers. For example, the lateral dimension of the bumps 150a3 is about 6 micrometers.

Since the thickness of the patterned photoresist layer 308′ is higher than the height of the bumps 150a1 and 150a2, the height of the bumps 150a3 may be greater than the height of the bumps 150a1 and 150a2. In some embodiments, the height difference between the bumps 150a1 and the bumps 150a2 is less than or substantially equal to 2 micrometers, and the height difference between the bumps 150a3 and the bumps 150a1 ranges from about 1 micrometer to about 2 micrometers. The bumps 150a1, 150a2 and 150a3 are collectively referred as to bumps 150a arranged in array.

Referring to FIG. 5G and FIG. 5H, after forming the bumps 150a3, the patterned photoresist layer 308′ is removed through a photoresist stripping process. In some embodiments, the photoresist stripping process includes an ash process or other suitable removal process of the patterned photoresist layer 308′.

After the patterned photoresist layer 306′ is removed, portions of the seed layer 304 that are uncovered by the bumps 150a1, 150a2 and 150a3 are revealed. A patterning or a removal process is then performed to remove the revealed portions of the seed layer 304 that are uncovered by the bumps 150a1, 150a2 and 150a3 until the surface of the semiconductor wafer 300 is revealed. After performing the patterning of the seed layer 304, the semiconductor wafer 300 including the bumps 150a1, 150a2 and 150a3 with various lateral dimensions are fabricated.

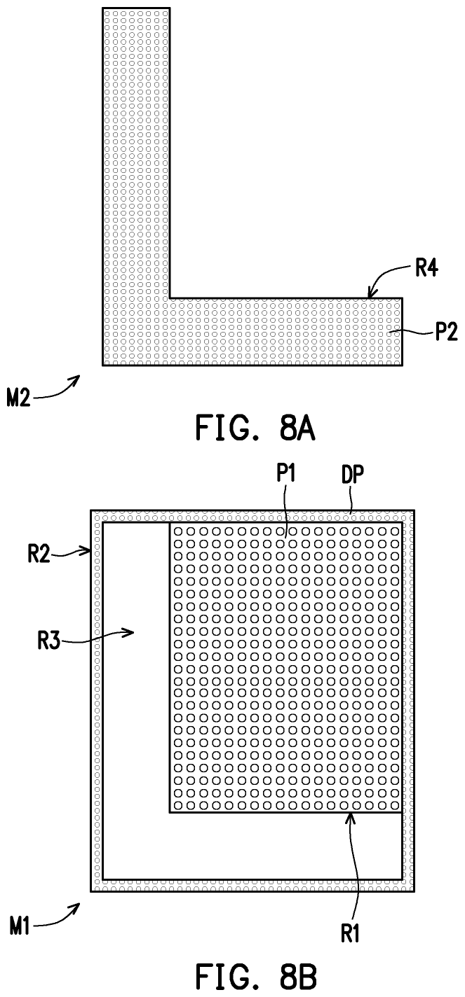

FIG. 7A through FIG. 7H are cross-sectional views schematically illustrating a process flow for fabricating a semiconductor wafer including bumps with various lateral dimensions in accordance with some embodiments of the present disclosure. FIG. 8A is a top view schematically illustrating a mask utilized in the photolithography process as shown in FIG. 7B. FIG. 8B is a top view schematically illustrating a mask utilized in the photolithography process as shown in FIG. 7F.

Referring to FIG. 7A, the details of the process illustrated in FIG. 7A are already described in accompany with FIG. 5A, and thus the detailed descriptions of FIG. 7A are omitted here.

Referring to FIG. 7B and FIG. 8A, after forming the photoresist layer 306, a patterning process (e.g., a photolithography process followed by a development process) of the photoresist layer 306 is performed such that a patterned photoresist layer 306″ is formed on the seed layer 304. Portions of the seed layer 304 are revealed by openings of the patterned photoresist layer 306″. A mask M2 illustrated in FIG. 8A is provided and a photolithography process followed by a development process is performed by using the mask M2 illustrated in FIG. 8A such that the pattern on the mask M2 can be transferred onto the patterned photoresist layer 306″.

As illustrated in FIG. 8A, the mask M2 may include multiple unit patterns arranged in array although only one unit pattern is illustrated in FIG. 8A. The unit pattern of the mask M2 includes a small CD pattern P2, wherein the small CD pattern P2 is distributed in a region R4. After forming the patterned photoresist layer 306″, the mask M2 is removed and a cleaning process may be performed.

Referring to FIG. 7C, a plating process is performed such that bumps 150a3 with small CD are formed on the revealed portions of the seed layer 304. The arrangement pitch and CD of the bumps 150a3 are determined by the large CD pattern P2 distributed in the region R4. In some embodiments, the lateral dimension of the bumps 150a3 ranges from about 5 micrometers to about 7 micrometers. For example, the lateral dimension of the bumps 150a3 is about 6 micrometers.

Referring to FIG. 7D, after forming the bumps 150a3, the patterned photoresist layer 306″ is removed through a photoresist stripping process. In some embodiments, the photoresist stripping process includes an ash process or other suitable removal process of the patterned photoresist layer 306″.

After the patterned photoresist layer 306″ is removed, portions of the seed layer 304 that are uncovered by the bumps 150a3 are revealed.

Referring to FIG. 7E, a photoresist layer 308 is formed on the revealed portions of the seed layer 304 as well as the bumps 150a3. In some embodiments, the photoresist layer 308 is formed on the seed layer 304 and the bumps 150a3 by a spin-coating process followed by a baking process. As illustrated in FIG. 7E, the thickness of the photoresist layer 308 is sufficient to entirely cover the bumps 150a3.

Referring to FIG. 7F and FIG. 8B, after forming the photoresist layer 308, a patterning process (e.g., a photolithography process followed by a development process) of the photoresist layer 308 is performed such that a patterned photoresist layer 308″ is formed on the seed layer 304 as well as the bumps 150a3. Portions of the seed layer 304 are revealed by openings of the patterned photoresist layer 308″. A mask M2 illustrated in FIG. 8B is provided and a photolithography process followed by a development process is performed by using the mask M1 illustrated in FIG. 8B such that the pattern on the mask M1 can be transferred onto the patterned photoresist layer 308″.

As illustrated in FIG. 8B, the mask M1 may include multiple unit patterns arranged in array although only one unit pattern is illustrated in FIG. 8B. The unit pattern of the mask M1 includes a large CD pattern P1 and a dummy pattern DP surrounding the large CD pattern P1, wherein the large CD pattern P1 is distributed in a region R1, and the dummy pattern DP is distributed in the periphery region R2. Furthermore, a pattern-free region R3 abuts the region R1 as well as the periphery region R2 such that the region R1 and the pattern-free region R3 are laterally surrounded by the periphery region R2. Furthermore, the pattern-free region R3 is corresponding to the region R4 as illustrated in FIG. 8A.

After forming the patterned photoresist layer 308″, the mask M1 is removed and a cleaning process may be performed.

Referring to FIG. 7G, a plating process is performed such that bumps 150a1 with large CD and bumps (e.g., dummy bumps) 150a2 with small CD are formed on the revealed portions of the seed layer 304. The arrangement pitch and CD of the bumps 150a1 are determined by the large CD pattern P1 distributed in the region R1, and the arrangement pitch and CD of the bumps 150a2 are determined by the dummy pattern DP distributed in the periphery region R2. In some embodiments, the lateral dimension of the bumps 150a1 ranges from about 40 to about 50 micrometers, and the lateral dimension of the bumps 150a2 ranges from about 5 micrometers to about 7 micrometers. For example, the lateral dimension of the bumps 150a1 is about 45 micrometers, and the lateral dimension of the bumps 150a2 is about 6 micrometers.

During the plating process, the bumps 150a1 and the bumps 150a2 are formed by different deposition rates due to different lateral dimensions of the revealed portions of the seed layer 304. Accordingly, the height of the bumps 150a1 may be greater than the height of the bumps 150a2. In some embodiments, the height difference between the bumps 150a1 and the bumps 150a2 is less than or substantially equal to 2 micrometers.

The arrangement pitch and CD of the bumps 150a2 may be substantially identical with the arrangement pitch and CD of the bumps 150a3.

Through proper control of the plating process, the height of the bumps 150a3 may be greater than the height of the bumps 150a1 and 150a2. In some embodiments, the height difference between the bumps 150a1 and the bumps 150a2 is less than or substantially equal to 2 micrometers, and the height difference between the bumps 150a3 and the bumps 150a1 ranges from about 1 micrometer to about 2 micrometers. The bumps 150a1, 150a2 and 150a3 are collectively referred as to bumps 150a arranged in array.

Referring to FIG. 7G and FIG. 7H, after forming the bumps 150a1 and 150a2, the patterned photoresist layer 308″ is removed through a photoresist stripping process. In some embodiments, the photoresist stripping process includes an ash process or other suitable removal process of the patterned photoresist layer 308″.

After the patterned photoresist layer 308″ is removed, portions of the seed layer 304 that are uncovered by the bumps 150a1, 150a2 and 150a3 are revealed. A patterning or a removal process is then performed to remove the revealed portions of the seed layer 304 that are uncovered by the bumps 150a1, 150a2 and 150a3 until the surface of the semiconductor wafer 300 is revealed. After performing the patterning of the seed layer 304, the semiconductor wafer 300 including the bumps 150a1, 150a2 and 150a3 with various lateral dimensions are fabricated.

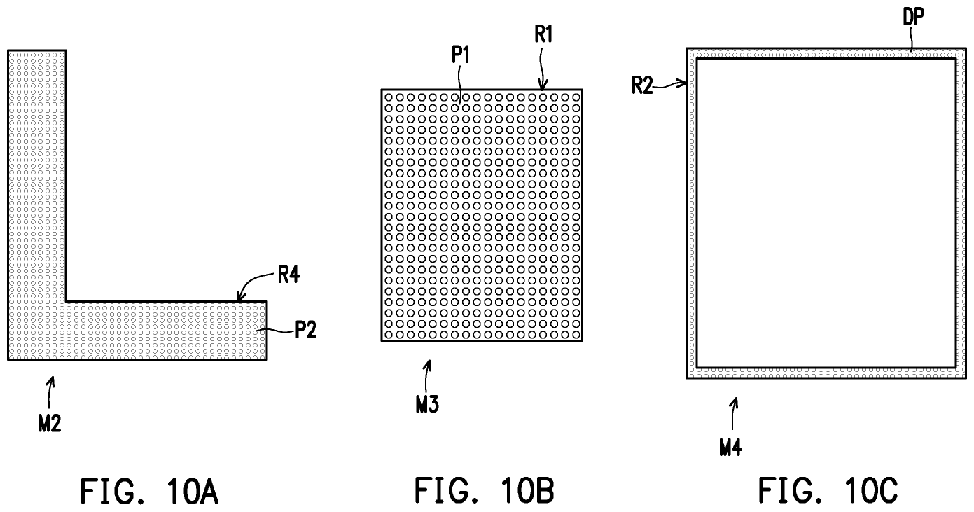

FIG. 9A through FIG. 9L are cross-sectional views schematically illustrating a process flow for fabricating a semiconductor wafer including bumps with various lateral dimensions in accordance with some embodiments of the present disclosure. FIG. 10A is a top view schematically illustrating a mask utilized in the photolithography process as shown in FIG. 9B. FIG. 10B is a top view schematically illustrating a mask utilized in the photolithography process as shown in FIG. 9F. FIG. 10C is a top view schematically illustrating a mask utilized in the photolithography process as shown in FIG. 9J.

The details of the process illustrated in FIG. 9A through FIG. 9E are already described in accompany with FIG. 5A through FIG. 5E, and thus the detailed descriptions of FIG. 9A through FIG. 9E are omitted here. Furthermore, the details of FIG. 10A are already described in accompany with FIG. 8A, and thus the detailed descriptions of FIG. 10A are omitted here.

Referring to FIG. 9F and FIG. 10B, after forming the photoresist layer 308, a patterning process (e.g., a photolithography process followed by a development process) of the photoresist layer 308 is performed such that a patterned photoresist layer 308″′ is formed on the seed layer 304 as well as the bumps 150a3. Portions of the seed layer 304 are revealed by openings of the patterned photoresist layer 308″′. A mask M3 illustrated in FIG. 10B is provided and a photolithography process followed by a development process is performed by using the mask M3 illustrated in FIG. 10B such that the pattern on the mask M3 can be transferred onto the patterned photoresist layer 308″′.

As illustrated in FIG. 10B, the mask M3 may include multiple unit patterns arranged in array although only one unit pattern is illustrated in FIG. 10B. The unit pattern of the mask M3 includes a large CD pattern P1, and the large CD pattern P1 is distributed in a region R1. After forming the patterned photoresist layer 308″′, the mask M3 is removed and a cleaning process may be performed.

Referring to FIG. 9G, a plating process is performed such that bumps 150a1 with large CD are formed on the revealed portions of the seed layer 304. The arrangement pitch and CD of the bumps 150a1 are determined by the large CD pattern P1 distributed in the region R1. In some embodiments, the lateral dimension of the bumps 150a1 ranges from about 40 to about 50 micrometers. For example, the lateral dimension of the bumps 150a1 is about 45 micrometers.

Through proper control of the plating process, the height of the bumps 150a3 may be greater than the height of the bumps 150a1. In some embodiments, the height difference between the bumps 150a1 is less than or substantially equal to 2 micrometers, and the height difference between the bumps 150a3 and the bumps 150a1 ranges from about 1 micrometer to about 2 micrometers.

Referring to FIG. 9G and FIG. 9H, after forming the bumps 150a1, the patterned photoresist layer 308″′ is removed through a photoresist stripping process. In some embodiments, the photoresist stripping process includes an ash process or other suitable removal process of the patterned photoresist layer 308″′ ′.

Referring to FIG. 9I, a photoresist layer 310 is formed on the revealed portions of the seed layer 304, the bumps 150a1 as well as the bumps 150a3. In some embodiments, the photoresist layer 310 is formed on the seed layer 304, the bumps 150a1 and the bumps 150a3 by a spin-coating process followed by a baking process. As illustrated in FIG. 9I, the thickness of the photoresist layer 310 is sufficient to entirely cover the bumps 150a1 and 150a3.

Referring to FIG. 9J and FIG. 10C, after forming the photoresist layer 310, a patterning process (e.g., a photolithography process followed by a development process) of the photoresist layer 310 is performed such that a patterned photoresist layer 310′ is formed on the seed layer 304, the bumps 150a1 as well as the bumps 150a3. Portions of the seed layer 304 are revealed by openings of the patterned photoresist layer 310′. A mask M4 illustrated in FIG. 10C is provided and a photolithography process followed by a development process is performed by using the mask M4 illustrated in FIG. 10C such that the pattern on the mask M4 can be transferred onto the patterned photoresist layer 310′.

As illustrated in FIG. 10C, the mask M4 may include multiple unit patterns arranged in array although only one unit pattern is illustrated in FIG. 10C. The unit pattern of the mask M4 includes a dummy pattern DP, and the dummy pattern DP is distributed in the periphery region R2. After forming the patterned photoresist layer 310′, the mask M4 is removed and a cleaning process may be performed.

Referring to FIG. 9K, a plating process is performed such that bumps (e.g., dummy bumps) 150a2 with small CD are formed on the revealed portions of the seed layer 304. The arrangement pitch and CD of the bumps 150a2 are determined by the dummy pattern DP distributed in the periphery region R2. In some embodiments, the lateral dimension of the bumps 150a2 ranges from about 5 micrometers to about 7 micrometers. For example, the lateral dimension of the bumps 150a2 is about 6 micrometers.

The bumps 150a1 and the bumps 150a2 are formed by different plating processes, and the height of the bumps 150a1 may be greater than the height of the bumps 150a2. In some embodiments, the height difference between the bumps 150a1 and the bumps 150a2 is less than or substantially equal to 2 micrometers. The arrangement pitch and CD of the bumps 150a2 may be substantially identical with the arrangement pitch and CD of the bumps 150a3.

Through proper control of the plating processes illustrated in FIG. 9B, FIG. 9G and FIG. 9K, the height of the bumps 150a3 may be greater than the height of the bumps 150a1 and 150a2. In some embodiments, the height difference between the bumps 150a1 and the bumps 150a2 is less than or substantially equal to 2 micrometers, and the height difference between the bumps 150a3 and the bumps 150a1 ranges from about 1 micrometer to about 2 micrometers. The bumps 150a1, 150a2 and 150a3 are collectively referred as to bumps 150a arranged in array.

Referring to FIG. 9K and FIG. 9L, after forming the bumps 150a1 and 150a2, the patterned photoresist layer 310′ is removed through a photoresist stripping process. In some embodiments, the photoresist stripping process includes an ash process or other suitable removal process of the patterned photoresist layer 310′.

After the patterned photoresist layer 310′ is removed, portions of the seed layer 304 that are uncovered by the bumps 150a1, 150a2 and 150a3 are revealed. A patterning or a removal process is then performed to remove the revealed portions of the seed layer 304 that are uncovered by the bumps 150a1, 150a2 and 150a3 until the surface of the semiconductor wafer 300 is revealed. After performing the patterning of the seed layer 304, the semiconductor wafer 300 including the bumps 150a1, 150a2 and 150a3 with various lateral dimensions are fabricated.

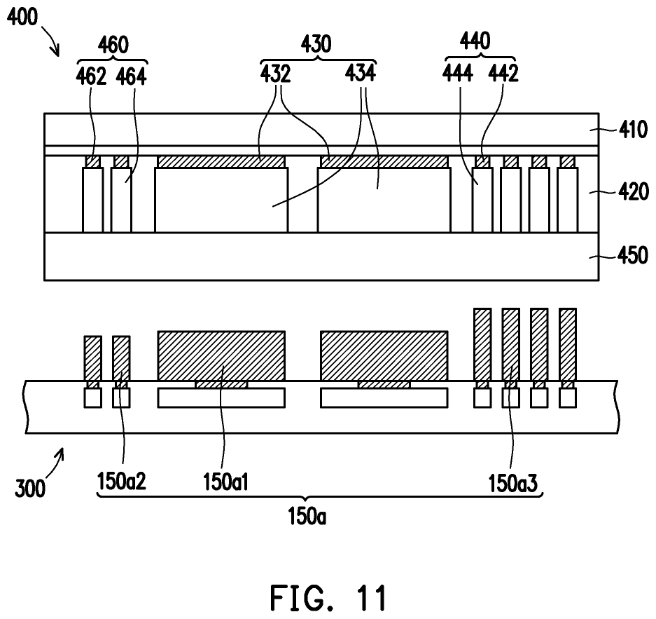

FIG. 11 through FIG. 13 are cross-sectional views schematically illustrating a process flow for fabricating a package structure in accordance with some embodiments of the present disclosure. In FIG. 11 through FIG. 13, semiconductor dies 400 are provided over the semiconductor wafer 300, and the semiconductor dies 400 illustrated in FIG. 11 through FIG. 13 are equivalent to the semiconductor dies 120a and 120b as illustrated in FIG. 1 through FIG. 4.

Referring to FIG. 11, the semiconductor dies 400 each including a semiconductor substrate 410, a passivation layer 420 disposed on the semiconductor substrate 410, first conductive terminals 430 embedded in the passivation layer 420, and second conductive terminals 440 embedded in the passivation layer 420 are provided. The first conductive terminals 430 and the second conductive terminals 440 are laterally encapsulated by the passivation layer 420. The first conductive terminals 430 are wider than the second conductive terminals 440. In other words, the lateral dimension of the first conductive terminals 430 are greater than the lateral dimension of the second conductive terminals 440. The ends of the first conductive terminals 430 and the ends of the second conductive terminals 440 substantially level with a surface of the passivation layer 420. In some embodiments, the semiconductor die 400 further includes a dielectric layer 450 (e.g., a non-conductive film (NCF)) disposed on the passivation layer 420, wherein the dielectric layer 450 covers and is in contact with the ends of the first conductive terminals 430, the ends of the second conductive terminals 440 as well as the surface of the passivation layer 420.

In some alternative embodiments, the semiconductor dies 400 further includes third conductive terminals 460 embedded in the passivation layer 420. The third conductive terminals 460 are laterally encapsulated by the passivation layer 420. The ends of the third conductive terminals 460 substantially level with the ends of the first conductive terminals 430, the ends of the second conductive terminals 440 and the surface of the passivation layer 420. Furthermore, the dielectric layer 450 covers and is in contact with the ends of the first conductive terminals 430, the ends of the second conductive terminals 440, the ends of the third conductive terminals 460 as well as the surface of the passivation layer 420.

The semiconductor dies 400 including the semiconductor substrate 410, the first conductive terminals 430, the second conductive terminals 440 and the dielectric layer 450 may be fabricated from a semiconductor wafer by a singulation process. In other words, the fabrication of the first conductive terminals 430, the second conductive terminals 440 and the dielectric layer 450 may be performed by a series of wafer level processes. Furthermore, the sidewalls of the passivation layer 420 and the sidewalls of the dielectric layer 450 are substantially aligned with the sidewalls of the semiconductor substrate 410. The number of the semiconductor dies 400 is not limited in the present application although only one of the semiconductor dies 400 is shown in FIG. 11.

As illustrated in FIG. 11, each one of the first conductive terminals 430 may include a bump 432 and solder portion 434 formed on the bump 432, each one of the second conductive terminals 440 may include a bump 442 and solder portion 444 formed on the bump 442, and each one of the third conductive terminals 460 may include a bump 462 and solder portion 464 formed on the bump 462. In some embodiments, the lateral dimension of the bumps 432 ranges from about 40 to about 50 micrometers, the lateral dimension of the bumps 442 ranges from about 5 micrometers to about 7 micrometers, and the lateral dimension of the bumps 462 ranges from about 5 micrometers to about 7 micrometers. For example, the lateral dimension of the bumps 432 is about 45 micrometers, the lateral dimension of the bumps 442 is about 6 micrometers, and the lateral dimension of the bumps 462 is about 6 micrometers. The lateral dimension of the solder portion 434 may be slightly greater than the lateral dimension of the bumps 432, the lateral dimension of the solder portion 444 may be slightly greater than the lateral dimension of the bumps 442, and the lateral dimension of the solder portion 464 may be slightly greater than the lateral dimension of the bumps 462. For example, the lateral dimension of the solder portion 434 is about 50 micrometers, the lateral dimension of the solder portion 444 is about 8 micrometers, and the lateral dimension of the solder portion 464 is about 8 micrometers.

The semiconductor wafer 300 including the bumps 150a with various bump widths, which is fabricated by the processes as illustrated in FIG. 5A through FIG. 5H, FIG. 7A through FIG. 7H or FIG. 9A through FIG. 9L, is provided. As illustrated in FIG. 11, the bumps 150a of the semiconductor wafer 300 includes the bumps 150a1, the bumps 150a2 and the bumps 150a3. Then, the semiconductor dies 400 are provided over the semiconductor wafer 300, wherein the bumps 150a1 are located under the first conductive terminals 430, the bumps 150a3 are located under the second conductive terminals 440, and the bumps 150a2 are located under the third conductive terminals 460. In some embodiments, the bumps 150a1 are wider than the bumps 150a2 and 150a3, and the bumps 150a3 are higher than the bumps 150a1. Furthermore, the bumps 150a1 may be higher than the bumps 150a2, as shown in FIG. 11. In some other embodiments, the bumps 150a1 and the bumps 150a2 are substantially identical in height, not shown in FIG. 11.

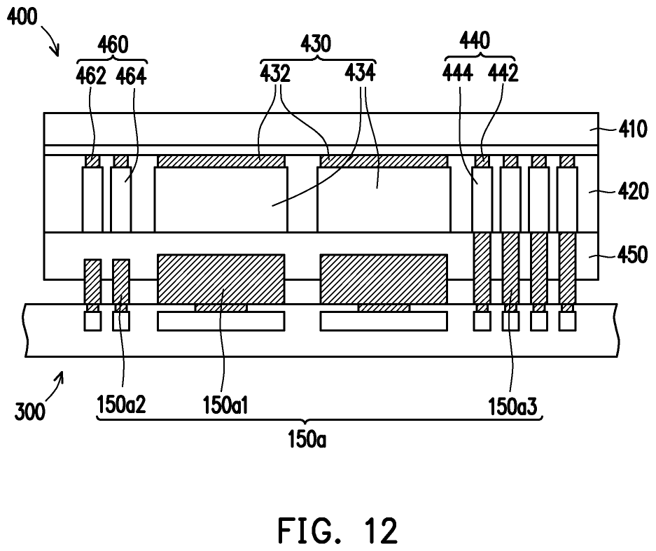

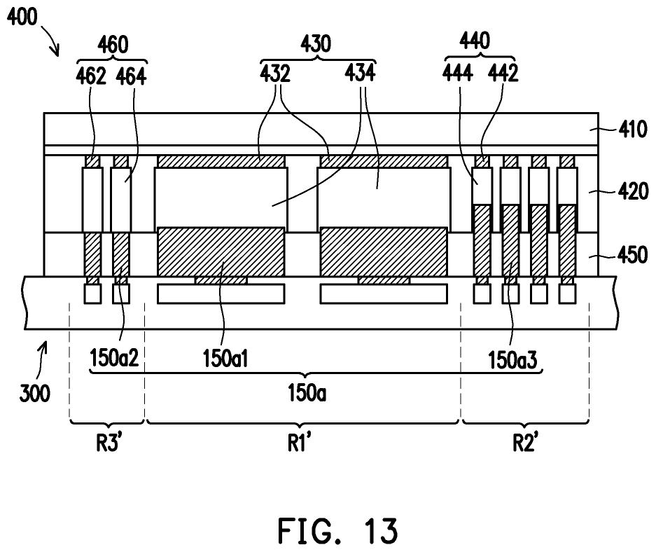

Referring to FIG. 12, a Chip-to-Wafer (CoW) bonding process (e.g., a thermal compression bonding (TCB) process) is performed. When performing the CoW bonding process, the semiconductor dies 400 are picked-up and pressed onto the semiconductor wafer 300 such that the bumps 150a1, 150a2 and 150a3 formed on the semiconductor wafer 300 protrude into the dielectric layer 450. At this stage, since the height of the bumps 150a3 is greater than the thickness of the dielectric layer 450, the bumps 150a3 pierce or penetrate through the dielectric layer 450 and the top ends of the bumps 150a3 are in contact with the solder portions 444. As illustrated in FIG. 12, at this stage, the bumps 150a1 and 150a2 are spaced apart from the solder portions 434 and 464 by the dielectric layer 450. The minimum distance between the bumps 150a1 and 150a2 the solder portions 434 and 464 may range from about 1 micrometer to about 2 micrometers. Furthermore, the gap between the bottom surface of the dielectric layer 450 and the top surface of the semiconductor wafer 300 on which the bumps 150 are distributed may range from about 1 micrometer to about 2 micrometers. Although the CoW bonding process is described in accompany with FIG. 12, the bonding process is not limited thereto. In some alternative embodiments, not shown in figures, a Wafer-to-Wafer (WoW) bonding process is performed to pick-up and press the semiconductor dies 400 in a semiconductor wafer onto the semiconductor wafer 300 such that the bumps 150a1, 150a2 and 150a3 formed on the semiconductor wafer 300 protrude into the dielectric layer 450. In some other embodiments, not shown in figures, a die-to-die bonding process is performed to pick-up and press the semiconductor dies 400 onto semiconductor die singulated from the semiconductor wafer 300 such that the bumps 150a1, 150a2 and 150a3 formed on the semiconductor wafer 300 protrude into the dielectric layer 450.

Referring to FIG. 13, after the top ends of the bumps 150a3 are in contact with the solder portions 444, the semiconductor dies 400 are further pressed downwardly until the dielectric layer 450 is in contact with the top surface of the semiconductor wafer 300. The semiconductor dies 400 are further pressed downwardly such that the top ends of the bumps 150a3 protrude into the solder portions 444 of the second conductive terminals 440, the bumps 150a1 protrude into the solder portions 434 of the first conductive terminals 430, and the top ends of the bumps 150a2 are in contact with the solder portions 464 of the third conductive terminals 460. Then, an annealing process is performed to ensure the electrical connections between the bumps 150a1, 150a2 and 150a3 as well as the solder portions 434, 444 and 464. It is noted that, the bumps 150a1, 150a2, 150a3, 432, 442, 462 as well as the solder portions 434, 444, 464 are collectively referred as to the conductive terminals 150 illustrated in FIG. 1 through FIG. 4.

In some embodiments, the solder portions 434 include extrusion portions laterally wrapping the bumps 150a1, and the solder portions 444 include extrusion portions laterally wrapping the bumps 150a3. The solder portions 464 may not include extrusion portions. As illustrated in FIG. 13, the bumps 150a1 are spaced apart from the dielectric layer 450 by the solder portions 434, and the bumps 150a3 are spaced apart from the dielectric layer 450 by the solder portions 444.

At this stage, since the lateral dimension of the bumps 150a3 is smaller than the lateral dimension of the bumps 150a1, the amount of solder extrusion resulted from each of the bumps 150a3 is less than the amount of solder extrusion resulted from each of the bumps 150a1. Accordingly, less amount of solder extrusion resulted from each of the bumps 150a3 can effectively prevent the short circuit issue occurred between the bumps 150a3 with small CD. Furthermore, since the bumps 150a3 protrude into solder portions 444, the cold joint (i.e., the open circuit) issue between the bumps 150a3 and the solder portions 444 can be effectively prevented.

As illustrated in FIG. 13, a package structure including a first substrate (e.g., the semiconductor wafer 300) and at least one second substrate (e.g., the semiconductor die 400) is provided. The first substrate (e.g., the semiconductor wafer 300) includes first bumps 150a1 with first lateral dimension and second bumps 150a3 with second lateral dimension. In other words, the first bumps 150a1 are wider than the second bumps 150a3, and the second bumps 150a3 are higher than the first bumps 150a1. The first bumps 150a1 are distributed in a first region R1′ (e.g., a large CD region) of the first substrate (e.g., the semiconductor wafer 300), and the second bumps 150a3 are distributed in the second region R2′ (e.g., a small CD region) of the first substrate (e.g., the semiconductor wafer 300), wherein the first lateral dimension is greater than the second lateral dimension, and a first bump height of the first bumps 150a1 is smaller than a second bump height of the second bumps 150a3. The second substrate (e.g., the semiconductor die 400) includes conductive terminals 430 and 430 electrically connected to the first bumps 150a1 and the second bumps 150a3.

In some embodiments, the package structure illustrated in FIG. 13 further includes a dielectric layer 450 (e.g., a non-conductive film) laterally encapsulating the first bumps 150a1 and the second bumps 150a3, wherein a thickness of the dielectric layer 450 (e.g., a non-conductive film) is smaller than the first bumps height of the first bumps 150a1 and the second bump height of the second bumps 150a3. In some embodiments, the package structure illustrated in FIG. 13 further includes a passivation layer 420 laterally encapsulating the conductive terminals 430 and 440, wherein the passivation layer 420 is in contact with the dielectric layer 450 (e.g., a non-conductive film). In some embodiments, the second bumps 150a3 protrude into the conductive terminals 440. In some embodiments, the first bumps 150a1 and the second bumps 150a2 protrude into the conductive terminals 430. In some embodiments, the first substrate (e.g., the semiconductor wafer 300) further includes third bumps 150a2 (e.g., dummy bumps) with third lateral dimension, and the third bumps 150a2 are distributed in a third region' R3 (e.g., a dummy region) of the first substrate (e.g., the semiconductor wafer 300). In some embodiments, as illustrated in FIG. 13, the third lateral dimension of the third bumps 150a2 is less than the first lateral dimension of the first bumps 150a1 and greater than the second lateral dimension of the second bumps 150a3. In some alternative embodiments, not shown in figures, the third lateral dimension of the third bumps 150a2 is less than the first lateral dimension of the first bumps 150a1 and substantially equals to the second lateral dimension of the second bumps 150a3. In some embodiments, a third bump height of the third bumps 150a2 is smaller than the first bump height of the first bump 150a1 as illustrated in FIG. 13 or substantially equals to the first bump height of the first bumps 150a1 (not illustrated in figures). In some embodiments, each of the conductive terminals 430 includes a bump portion 432 and a solder portion 434 covering the bump portion 432, and the solder portion 434 of each of the conductive terminals 430 is in contact with to one of the first bumps 150a1; each of the conductive terminals 440 includes a bump portion 442 and a solder portion 444 covering the bump portion 442, and the solder portion 444 of each of the conductive terminals 440 is in contact with to one of the second bumps 150a3; and each of the conductive terminals 460 includes a bump portion 462 and a solder portion 464 covering the bump portion 462, and the solder portion 464 of each of the conductive terminals 460 is in contact with to one of the second bumps 150a2.

The second substrate (e.g., the semiconductor die 400) is bonded to the first substrate (e.g., the semiconductor wafer 300). The passivation layer 420 is bonded to the dielectric layer 450, the first conductive terminals 430 are bonded to the first bumps 150a1, the second conductive terminals 440 are bonded to the second bumps 150a3, and the first conductive terminals 430 are wider than the second conductive terminals 440. In some embodiments, a height difference between the first bumps 150a1 and the second bumps 150a3 ranges from about 1 micrometer to about 2 micrometers. In some embodiments, the second bumps 150a3 protrude into the second conductive terminals 440. In some embodiments, the first substrate (e.g., the semiconductor wafer 300) further includes third bumps or dummy bumps 150a2 laterally encapsulated by the dielectric layer 420. In some embodiments, the first bumps 150a1 are higher than the dummy bumps 150a2. In some alternative embodiments, not illustrated in figures, the first bumps 150a1 and the dummy bumps 150a2 are substantially identical in height.

After the second substrate (e.g., the semiconductor die 400) is bonded to the first substrate (e.g., the semiconductor wafer 300), a process for fabricating the insulating encapsulation 130 (as illustrated in FIG. 1 through FIG. 4) and a singulation process of such reconstructed wafer may be performed such that multiple singulated package structures are obtained. The above-mentioned singulated package structures may be the same as the structure including the semiconductor dies 120, the insulating encapsulation 130, the interposer substrate 140, and the conductive terminals 150 (as illustrated in FIG. 1 through FIG. 4).

In the above-mentioned embodiments, solder extrusion of the solder portions 434 and 444 as well as the bleeding of the dielectric layer 450 can be effectively controlled due to the height difference of bumps 150a1 and 150a3. Accordingly, unaccepted cold joint and/or short circuit between the second substrate (e.g., the semiconductor die 400) and the first substrate (e.g., the semiconductor wafer 300) can be prevented, and the joint yields of the package structure can increase.

In accordance with some embodiments of the disclosure, a package structure including a first substrate and a second substrate is provided. The first substrate includes first bumps with first lateral dimension and second bumps with second lateral dimension. The first bumps are distributed in a first region of the first substrate, and the second bumps are distributed in the second region of the first substrate, wherein the first lateral dimension is greater than the second lateral dimension, and a first bump height of the first bumps is smaller than a second bump height of the second bumps. The second substrate includes conductive terminals electrically connected to the first bumps and the second bumps. In some embodiments, the package structure further includes a non-conductive film laterally encapsulating the first bumps and the second bumps, wherein a thickness of the non-conductive film is smaller than the first bumps height and the second bump height. In some embodiments, the package structure further includes a passivation layer laterally encapsulating the conductive terminals, wherein the passivation layer is in contact with the non-conductive film. In some embodiments, the second bumps protrude into the conductive terminals. In some embodiments, the first bumps and the second bumps protrude into the conductive terminals. In some embodiments, the first substrate further includes third bumps with third lateral dimension, and the third bumps are distributed in a third region of the first substrate. In some embodiments, the third lateral dimension is less than the first lateral dimension and greater than the second lateral dimension. In some embodiments, the third lateral dimension is less than the first lateral dimension and substantially equals to the second lateral dimension. In some embodiments, a third bump height of the third bumps is smaller than the first bump height or substantially equals to the first bump height. In some embodiments, each of the conductive terminals includes a bump portion and a solder portion covering the bump portion, and the solder portion of each of the conductive terminals is in contact with to one of the first bumps or one of the second bumps.

In accordance with some other embodiments of the disclosure, a package structure including a substrate and a semiconductor die is provided. The substrate includes first bumps, second bumps, and a dielectric layer laterally encapsulating the first and second bumps, wherein the first bumps are wider than the second bumps, and the second bumps are higher than the first bumps. The semiconductor die is bonded to the substrate. The semiconductor die includes a passivation layer bonded to the dielectric layer, first conductive terminals embedded in the passivation layer, and second conductive terminals embedded in the passivation layer, wherein the first conductive terminals are bonded to the first bumps, the second conductive terminals are bonded to the second bumps, and the first conductive terminals are wider than the second conductive terminals. In some embodiments, a height difference between the first bumps and the second bumps ranges from about 1 micrometer to about 2 micrometers. In some embodiments, the second bumps protrude into the second conductive terminals. In some embodiments, the substrate further includes dummy bumps laterally encapsulated by the dielectric layer. In some embodiments, the first bumps are higher than the dummy bumps. In some embodiments, the first bumps and the dummy bumps are substantially identical in height.

In accordance with some other embodiments of the disclosure, a method for fabricating a package structure is provided. The method includes the following steps. A first substrate including first bumps and second bumps is provided, wherein the first bumps are wider than the second bumps, and the second bumps are higher than the first bumps first bumps. A second substrate including conductive terminals and a passivation layer laterally encapsulating the conductive terminals are provided. A dielectric layer is formed on the second substrate to cover the passivation layer and the conductive terminals. A bonding process of the first substrate and the second substrate is performed such that the first bumps and the second bumps penetrate through the dielectric layer and protrude into solder portions of the conductive terminals. In some embodiments, the first bumps and the second bumps are formed through different plating processes. In some embodiments, the bonding process of the first substrate and the second substrate includes: pressing the second substrate having the dielectric layer formed thereon onto the first substrate such that the first bumps and the second bumps are embedded in the dielectric layer, and top ends of the second bumps are in contact with the solder portions of the conductive terminals; and further pressing the second substrate such that the top ends of the second bumps protrude into the solder portions of the conductive terminals and top ends of the first bumps are in contact with the solder portions of the conductive terminals. In some embodiments, the bonding process of the first substrate and the second substrate includes a thermal compression bonding (TCB) process.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A package structure, comprising:
a first substrate comprising first bumps with first lateral dimension and second bumps with second lateral dimension, the first bumps being distributed in a first region of the first substrate, and the second bumps being distributed in the second region of the first substrate, wherein the first lateral dimension is greater than the second lateral dimension, and a first bump height of the first bumps is smaller than a second bump height of the second bumps; and
a second substrate comprising conductive terminals electrically connected to the first bumps and the second bumps.

2. The package structure of claim 1 further comprising:
a non-conductive film laterally encapsulating the first bumps and the second bumps, wherein a thickness of the non-conductive film is smaller than the first bumps height and the second bump height.

3. The package structure of claim 2 further comprising:
a passivation layer laterally encapsulating the conductive terminals, wherein the passivation layer is in contact with the non-conductive film.

4. The package structure of claim 1, wherein the second bumps protrude into the conductive terminals.

5. The package structure of claim 1, wherein the first bumps and the second bumps protrude into the conductive terminals.

6. The package structure of claim 1, wherein the first substrate further comprises third bumps with third lateral dimension, and the third bumps are distributed in a third region of the first substrate.

7. The package structure of claim 6, wherein the third lateral dimension is less than the first lateral dimension and greater than the second lateral dimension.

8. The package structure of claim 6, wherein the third lateral dimension is less than the first lateral dimension and substantially equals to the second lateral dimension.

9. The package structure of claim 6, wherein a third bump height of the third bumps is smaller than the first bump height or substantially equals to the first bump height.

10. The package structure of claim 1, wherein each of the conductive terminals comprises a bump portion and a solder portion covering the bump portion, and the solder portion of each of the conductive terminals is in contact with to one of the first bumps or one of the second bumps.

11. A package structure, comprising:
a substrate comprising first bumps, second bumps, and a dielectric layer laterally encapsulating the first and second bumps, wherein the first bumps are wider than the second bumps, and the second bumps are higher than the first bumps; and
a semiconductor die bonded to the substrate, the semiconductor die comprising a passivation layer bonded to the dielectric layer, first conductive terminals embedded in the passivation layer, and second conductive terminals embedded in the passivation layer, wherein the first conductive terminals are bonded to the first bumps, the second conductive terminals are bonded to the second bumps, and the first conductive terminals are wider than the second conductive terminals.

12. The package structure of claim 11, wherein a height difference between the first bumps and the second bumps ranges from about 1 micrometer to about 2 micrometers.

13. The package structure of claim 11, wherein the second bumps protrude into the second conductive terminals.

14. The package structure of claim 11, wherein the substrate further comprises dummy bumps laterally encapsulated by the dielectric layer.

15. The package structure of claim 14, wherein the first bumps are higher than the dummy bumps.

16. The package structure of claim 14, wherein the first bumps and the dummy bumps are substantially identical in height.

17. A method, comprising:
providing a first substrate comprising first bumps and second bumps, wherein the first bumps are wider than the second bumps, and the second bumps are higher than the first bumps first bumps;
providing a second substrate comprising conductive terminals and a passivation layer laterally encapsulating the conductive terminals;
forming a dielectric layer on the second substrate to cover the passivation layer and the conductive terminals; and
performing a bonding process of the first substrate and the second substrate such that the first bumps and the second bumps penetrate through the dielectric layer and protrude into solder portions of the conductive terminals.

18. The method of claim 17, wherein the first bumps and the second bumps are formed through different plating processes.

19. The method of claim 17, wherein the bonding process of the first substrate and the second substrate comprises:
pressing the second substrate having the dielectric layer formed thereon onto the first substrate such that the first bumps and the second bumps are embedded in the dielectric layer, and top ends of the second bumps are in contact with the solder portions of the conductive terminals; and
further pressing the second substrate such that the top ends of the second bumps protrude into the solder portions of the conductive terminals and top ends of the first bumps are in contact with the solder portions of the conductive terminals.

20. The method of claim 17, wherein the bonding process of the first substrate and the second substrate comprises a thermal compression bonding (TCB) process.
